(19) United States
(12) Patent Application Publication
(10) Pub. No.: US 2021/0107680 A1
(43) Pub. Date: Apr. 15, 2021

(54) OVERHEAT DETECTOR EVENT VISUALIZATION

(71) Applicant: Kidde Technologies, Inc., Wilson, NC (US)

(72) Inventors: Avinash Chandrashekar Vijay Reddy, Bangalore (IN); Vinod Maruti Naik, Uttara Kannada (IN)

(21) Appl. No.: 17/002,934

(22) Filed: Aug. 26, 2020

(30) Foreign Application Priority Data
Oct. 15, 2019 (IN) 201911041773

(51) Int. Cl. B64D 45/00; B64F 5/60; G06T 7/73; G06T 7/00

(52) U.S. Cl. CPC B64D 45/0005; B64F 5/60; G01R 31/008; G06T 7/001; G06T 7/74

(57) ABSTRACT

Systems, methods, and computer program products for aircraft event visualization are provided. Aspects include receiving fault data associated with an aircraft, the fault data comprising an error message for the aircraft, determining a location on the aircraft associated with the error message based on one or more lookup tables associated with the aircraft, and providing an indication of the location to a user.

### CROSS-REFERENCE TO RELATED APPLICATION

This application claims the benefit of Indian Patent Application No. 201911041773 filed Oct. 15, 2019, which is incorporated herein by reference in its entirety.

### BACKGROUND

The present invention generally relates to aircraft maintenance, and more specifically, to overheat detector event visualization.

The architecture of aircraft are evolving based on application needs, customer needs, market segments and the availability of advanced technologies. In the process there are attempts to make aircraft more intelligent, more electrical and more data driven. Considering the cost of an aircraft design life cycle and operations, having a modular and re-usable architecture while still maintaining robustness and reliability of the design can be a challenge.

Continuous fire detectors (CFD) which are a part of over heat detection system (OHDS) are installed on aircraft to detect overheat/hot air leak events. The OHDS detects and localizes an ambient overheat in the vicinity of any hot air ducts which run throughout the engine pylons, wings, fuselage, and the belling fairing of an aircraft. Based on safety requirements, CFDs provide more coverage of a fire hazard area than any type of spot type temperature detector. For redundancy purposes, two sensing elements typically run in parallel in the CFD system.

### SUMMARY

Embodiments of the present disclosure are directed to system. A non-limiting example of the system includes a processor communicatively coupled to a memory, the processor configured to perform receiving fault data associated with an aircraft, the fault data comprising an error message for the aircraft, determining a location on the aircraft associated with the error message based on one or more lookup tables associated with the aircraft, and providing an indication of the location to a user.

Embodiments of the present disclosure are directed to a method for aircraft event visualization. A non-limiting example of the method includes receiving fault data associated with an aircraft, the fault data comprising an error message for the aircraft, determining a location on the aircraft associated with the error message based on one or more lookup tables associated with the aircraft, and providing an indication of the location to a user.

Embodiments of the present disclosure are directed to a computer program product for aircraft event visualization. A non-limiting examiner of the computer program product includes a non-transitory computer readable medium with instruction embedded therein, the instructions operable to cause a processor to perform receiving fault data associated with an aircraft, the fault data comprising an error message for the aircraft, determining a location on the aircraft associated with the error message based on one or more lookup tables associated with the aircraft, and providing an indication of the location to a user.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 is a perspective view of an aircraft that may incorporate embodiments of the present disclosure;

FIG. 2a depicts an exemplary message that can be recorded and displayed according to one or more embodiments;

FIG. 2b depicts an exemplary localization table according to one or more embodiments;

FIG. 3 depicts a block diagram of a system for aircraft event visualization according to one or more embodiments;

FIG. 4 depicts a block diagram of an augmented reality display on a user device according to one or more embodiments; and

FIG. 5 depicts a flow diagram of a method for aircraft event visualization according to one or more embodiments.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

### DETAILED DESCRIPTION

Various embodiments of the invention are described herein with reference to the related drawings. Alternative embodiments of the invention can be devised without departing from the scope of this invention. Various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. Moreover, the various tasks and process steps described herein can be incorporated into a more comprehensive procedure or process having additional steps or functionality not described in detail herein.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” may be understood to include any integer number greater than or equal to one, i.e. one, two, three, four, etc. The terms “a plurality” may be understood to include any integer number greater than or equal to two, i.e. two, three, four, five, etc. The term “connection” may include both an indirect “connection” and a direct “connection.”

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

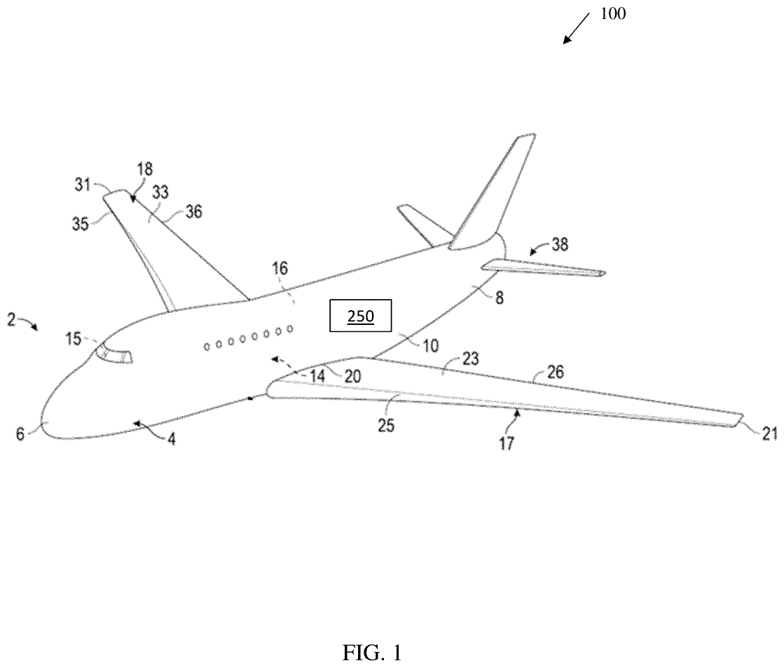

Referring now to the figures, FIG. 1 depicts a perspective view of an aircraft 2 that may incorporate embodiments of the present disclosure. Aircraft 2 includes a fuselage 4 extending from a nose portion 6 to a tail portion 8 through a body portion 10. Body portion 10 houses an aircraft cabin 14 that includes a crew compartment 15 and a passenger or cargo compartment 16. Body portion 10 supports a first wing 17 and a second wing 18. First wing 17 extends from a first root portion 20 to a first tip portion 21 through a first airfoil portion 23. First airfoil portion 23 includes a leading edge 25 and a trailing edge 26. Second wing 18 extends from a second root portion (not shown) to a second tip portion 31 through a second airfoil portion 33. Second airfoil portion 33 includes a leading edge 35 and a trailing edge 36. Tail portion 8 includes a stabilizer 38. Aircraft 2 includes an engine 54 configured to provide propulsion to the aircraft 2.

Turning now to an overview of technologies that are more specifically relevant to aspects of the invention, continuous fire detectors (CFD) which are a part of overheat detection system (OHDS) 250 can be installed on aircraft (for example, aircraft 2) to detect overheat/hot air leak events. The OHDS detects and localizes an ambient overheat near any hot air ducts which run throughout the engine pylons, wings, fuselage, and the belling fairing of an aircraft. Based on safety requirements, CFDs provide more coverage of a fire hazard area than any type of spot type temperature detector. For redundancy purposes, two sensing elements typically run in parallel in the CFD system. A primary purpose of the detection monitoring system is to prevent any damage to structural and system components, which could result from duct leak or rupture. In addition, secondary functions include identifying the location of the overheat event as a troubleshooting aid. The purpose of this localization function is to provide maintenance personnel with a general area to focus troubleshooting efforts, saving both time and effort in restoring the OHDS functionality.

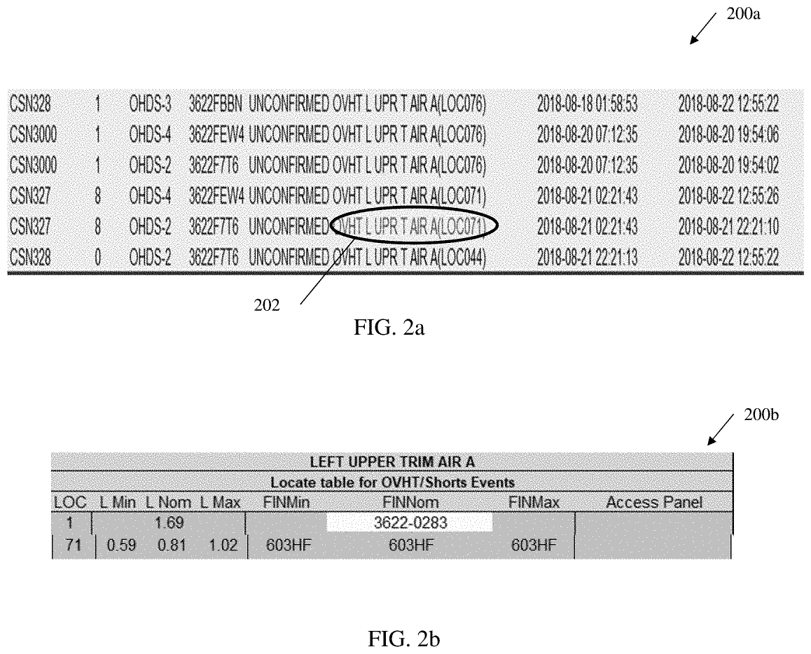

In typical systems, whenever there is an overheat/short event occurring in an aircraft, the localization value and the fault message are recorded in the electronic centralized aircraft monitor (ECAM). An ECAM is a system that monitors aircraft functions and relays them to the pilots. It also produces messages detailing failures and in certain cases, lists procedures to undertake to correct the problem. FIG. 2a depicts an exemplary message that can be recorded and displayed according to one or more embodiments. As shown in FIG. 2a, the message list 200a includes a number of messages for display along with accompanying data. Based on the localization value and the error message in the messages, a maintenance crew should be able to go through the localization tables to identify the area. An exemplary message 202 is depicted in FIG. 2a. From this message 202, a maintenance person must go through each localization table to identify the area of possible failure/fault. For most aircraft configurations there can be about 30 to 40 event tables and identifying the correct event table and getting the error message can take a long time and can be subject to error by maintenance personnel. As an example, the exemplary message 202 reads OVHT L UPR T AIR A(LOC 071). This message conveys that an error has occurred on the left upper trim air location in loop A sensing element at location 71. To understand what location 71 is, a maintenance crew would have to go to the left upper trim air, loop A localization table and then find what location 71 says about where the location is. FIG. 2b depicts an exemplary localization table 200b. As shown in the localization table 200b, the designated part number (603 HF) which indicates the part number is shown. Also, the table 200b provides a possible distance at which the fault was triggered (i.e., 0.059 inches to 1.02 inches). With this data taken from the table 200b, the maintenance crew would have to go and identify the error location to troubleshoot. This referencing to various tables to identify potential failure locations is cumbersome and can lead to wasted time and potential error in misreading tables and messages.

The above-described aspects of the invention address the shortcomings of the prior art by providing a three-dimensional (3D) visualization tool with augmented reality which takes an error massage as an input and graphically displays where in an aircraft the identified error is located. The 3D visualization tool can receive an error massage as an input and once a user (e.g., maintenance crew) enters the error message into the tool, the tool will graphically display where in the aircraft the identified error has occurred. Once the error location is identified by the user, the tool can further identify the relevant aircraft element or component that requires the maintenance. The visualization tool also suggests tool kits or equipment required to perform the maintenance activity. This can be done utilizing a user device with a display and camera. The camera can record video data and/or image data and display on the user device. The visualization tool can overlay an augmented reality cue or indication on the display over the video or images to show the exact location and component that requires the maintenance. In addition, the tool can suggest certain maintenance operations to be performed on the component that requires maintenance based on the images of the component taken by the camera on the user device.

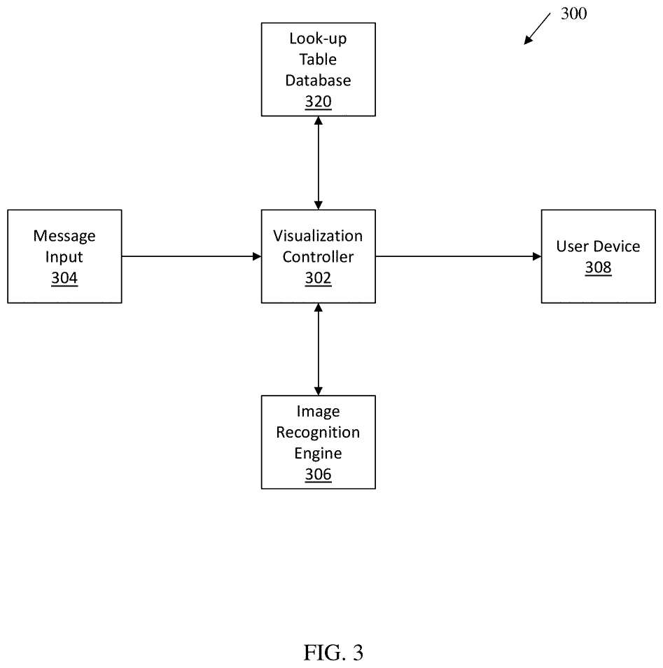

FIG. 3 depicts a block diagram of a system for aircraft event visualization according to one or more embodiments. The system 300 includes a visualization controller 302, a message input 304, an image recognition engine 306, a look-up table database 320, and a user device 308. In one or more embodiments, the visualization controller 302 can receive a message input 304. The message input 304 can include the message format described in FIG. 2a. Based on the message input 304, the visualization controller 302 can access a look-up table database 320 that includes descriptions of the various codes and descriptions found in a message from the message input 304. From this look-up table database, the visualization controller 302 is able to provide a candidate maintenance location on the aircraft based on the content of the message. As mentioned above, the message content can include information related to the location of a malfunctioning item. This information is typically in a code that requires a maintenance person to utilize one or more lookup tables to decipher. The visualization controller 302, instead, utilizes the message content and compares the information to lookup tables in the lookup table database 320 to assist with directing a maintenance person or user to the candidate maintenance location. In addition, the candidate maintenance location can be provided to the user utilizing augmented reality technology and displayed on the user device 308. In one or more embodiments, the visualization controller 302 can be connected to network to access data from the internet or other resources. The visualization controller 302 can analyze the message input 304 and search for information through the network to determine location and maintenance information (including repair strategies or operations) associated with the message input 304 to guide a user to the repair item location on the aircraft. As briefly mentioned above, aircrafts can be subjected to overheat events and short events that can trigger a message to be created to notify maintenance of an issue. These messages can be generated by the overheat detection systems (OHDS) on an aircraft when an event is present. The message input 304 can be received from the OHDS and transmitted to the visualization controller 302.

In one or more embodiments, the OHDS can utilize optical fire detectors to detect fire and overheat events on an aircraft. Optical Fire Detectors are another type of fire/overheat detector which work on the principle of Fiber Bragg grating. Optical fire detectors are also used to event locate the overheat occurrence in the installed location similar to the OHDS. In some embodiments, the visualization system 200 can be extended to optical fire detectors.

In one or more embodiments, the user device 308 includes a camera. The camera can be utilized to collect video and images of the candidate repair location on the aircraft. The images and video can be displayed on the user device 308 through a display. In one or more embodiments, the visualization controller 302 can overlay certain augmented reality cues on the images or video displayed on the user device 308 to guide the user to different candidate repair items shown on the display of the user device 308.

The camera can be any type of camera such as, for example, digital, infrared, and the like. The camera can capture media associated with the repair item such as images (or series of images) of the repair item, video of the repair item as it is being operated or as a user is manipulating the repair item or images of various components of the repair item. Using an image recognition 306, the visualization controller 302 can analyze the media captured by the camera to assist in identifying the repair item and potentially the cause of the malfunction of the repair item. Also, a repair methodology or operation can be determined using both the media and the any additional data obtained from a network and/or stored locally on the system 300 (e.g., the lookup table database 320).

In one or more embodiments, the camera can capture an image, a series of images, and/or video of various components for a repair item. The message input 304 can assist with determining the potential candidate repair location. Once the repair location and candidate repair items are determined, the visualization controller 302 can access data associated with the candidate repair items through accessing a network and server such as a manufacturer server or maintenance server. For example, for an electrical issue with an aircraft item, a manufacturer server can store images or videos of certain components that are working within normal tolerances. These images can be utilized as reference images for comparison to any candidate repair components of the aircraft. While analyzing the message input 304, the visualization controller 302 can identify candidate repair components that could be causing the overheat/short event for the aircraft. The camera can capture images of the candidate repair components and the visualization controller 302 and image recognition engine 306 can compare these images to the reference images (e.g., historical images) using image analyzation techniques, to determine any changes between the reference images and the images of the candidate repair components. A comparison score can be obtained based on the changes between the images. This may be performed by comparing pixel values at the same locations in the candidate repair component image and the reference image, or by any other known image comparison tool. A difference in pixel value at one location in the candidate repair component image and the reference image indicates a change between the candidate repair component image and the reference image. The absolute values of all the pixel differences between candidate repair component image and the reference image may then be summed to generate a comparison score. The pixel comparisons may be made, for example, based on a change in color, change in brightness, etc. In one or more embodiments, if the comparison score exceeds a threshold value, the visualization controller 302 can determine that the candidate repair component is causing the overheat/short event. The visualization controller 302 can search the network, for example, to obtain a repair method for repairing the candidate repair component. The repair method steps can be overlaid on the display of the user device 308 providing step by step instructions for any repairs.

In one or more embodiments, the display on the user device 308 can be further utilized to overlay augmented reality cues on images or video displayed on the user device 308. These augmented reality cues can assist with guiding a user to the candidate repair item at the candidate repair location on the aircraft. This can be performed in one or more steps to display multiple views of the aircraft guiding the user to the candidate location on the aircraft. For example, a first view can show the entire aircraft with an augmented reality cue indicating a broader location. For example, a top down view of the aircraft can be shown on the display of the user device 308 with a wing having an augmented reality cue indicating that the aircraft wing on the left hand side is the location of the candidate repair. As the user device 308 is moved closer to the wing, the display can then indicate smaller compartment, such as, hatches or panels with augmented reality cues overlaid indicating which hatch or panel to remove to access the interior components of the wing. When the candidate location within the aircraft is reached, the user can obtain images or video of the candidate location and the visualization controller 302 overlays the augmented reality cues to indicate the location of a specific repair component or item that needs either repair or replacement based on the message input 304.

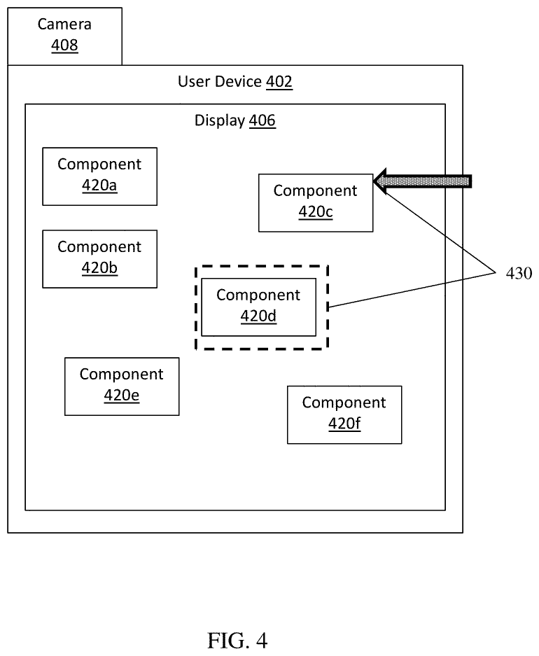

FIG. 4 depicts a block diagram of an augmented reality display on a user device according to one or more embodiments. In one or more embodiments, the user device 402 includes a display 406 and a camera 408. The user device 402 can be the user device 308 depicted in FIG. 3. In one or more embodiments, any of the hardware referenced in the system 300 and the user device 402 can be implemented by executable instructions and/or circuitry such as a processing circuit and memory. The processing circuit can be embodied in any type of central processing unit (CPU), including a microprocessor, a digital signal processor (DSP), a microcontroller, an application specific integrated circuit (ASIC), a field programmable gate array (FPGA), or the like. Also, in embodiments, the memory may include random access memory (RAM), read only memory (ROM), or other electronic, optical, magnetic, or any other computer readable medium onto which is stored data and algorithms as executable instructions in a non-transitory form. In some embodiments, the user device 402 can include any of the components found in the system 300 described with reference to FIG. 3. In other embodiments, the user device 302 can communication through a network connection with another device (e.g., server, computer, other user device, etc.) for processing operations of system 300.

In one or more embodiments, the user device 402 can utilize the display 406 to display images of the aircraft received from a server or stored on the user device 402. The display can display, for example, components 420a-420f of the aircraft. The images of the components 420a-420f can be taken in real time from images or video of the camera 408. Based on the processing described above, the visualization controller 302 (from FIG. 3) can overlay augmented reality cues 430 indicating what components 420a-420f are candidate repair items for the user of the user device 402. In the illustrated example, component 420c and 420d are candidate repair items. The augmented reality cues 430 can be any type of cue to draw a user's attention to the item while collecting images of the candidate repair location. For example, an arrow, a circle or box, a highlighting cue, or any other cue can be utilized to overlay on the display images. In one or more embodiments, the user can provide inputs to the user device 402 and display 406. For example, the user device 402 can include a touch screen display and/or additional buttons or inputs. As described above, images of components in good working order (historical image data) can be obtained from a manufacturer database or stored in a local database or on the user device. This historical image data can be utilized to show the user of the user device 402 how the components 420a-420f should look when installed correctly and/or working properly. The user can provide an input to, for example, the touch screen which allows the user to toggle between an image of the component from the historical images and an image of the component in present condition. This can assist the user with seeing a difference while repairing the item.

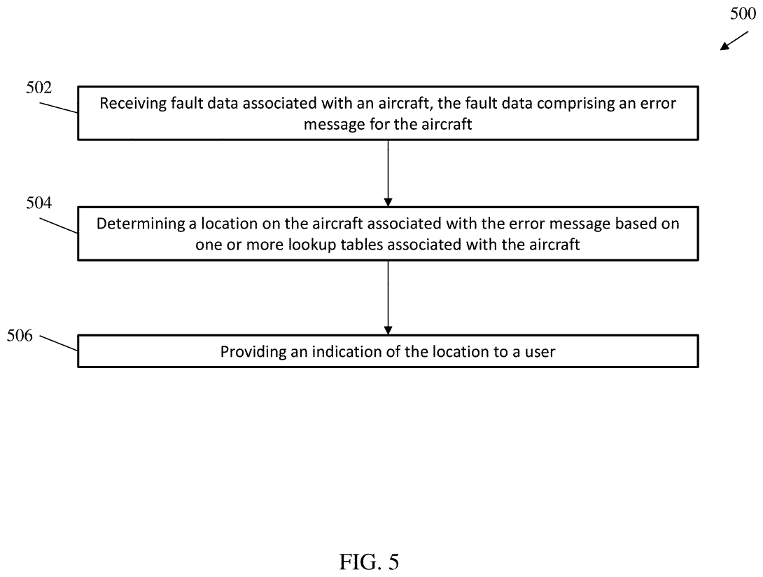

FIG. 5 depicts a flow diagram of a method for aircraft event visualization according to one or more embodiments. The method 500 includes receiving fault data associated with an aircraft, the fault data comprising an error message for the aircraft, as shown in block 502. Also, the method 500, at block 504, includes determining a location on the aircraft associated with the error message based on one or more lookup tables associated with the aircraft. And at block 506, the method 500 includes providing an indication of the location to a user.

Additional processes may also be included. It should be understood that the processes depicted in FIG. 5 represent illustrations, and that other processes may be added or existing processes may be removed, modified, or rearranged without departing from the scope and spirit of the present disclosure.

The term “about” is intended to include the degree of error associated with measurement of the particular quantity based upon the equipment available at the time of filing the application. For example, “about” can include a range of ±8% or 5%, or 2% of a given value.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

While the present disclosure has been described with reference to an exemplary embodiment or embodiments, it will be understood by those skilled in the art that various changes may be made and equivalents may be substituted for elements thereof without departing from the scope of the present disclosure. In addition, many modifications may be made to adapt a particular situation or material to the teachings of the present disclosure without departing from the essential scope thereof. Therefore, it is intended that the present disclosure not be limited to the particular embodiment disclosed as the best mode contemplated for carrying out this present disclosure, but that the present disclosure will include all embodiments falling within the scope of the claims.

What is claimed is:

1. A method for aircraft event visualization, the method comprising:
receiving fault data associated with an aircraft, the fault data comprising an error message for the aircraft;
determining a location on the aircraft associated with the error message based on one or more lookup tables associated with the aircraft; and
providing an indication of the location to a user.

2. The method of claim 1, further comprising:
determining a fault associated with the aircraft based on the error message;
determining a candidate maintenance operation based on the fault;
providing the candidate maintenance operation to the user.

3. The method of claim 1, wherein providing the indication of the location to the user comprises:
generating a graphical representation of the aircraft;
displaying the graphical representation of the aircraft on a display;
overlaying the indication on the location on the aircraft in the graphical representation.

4. The method of claim 3, further comprising:
receiving video data associated with the location on the aircraft;
segmenting the video data into one or more images;
determining historical images for installed components at the location on the aircraft based on the one or more images;
comparing the one or more images with the historical images to determine a fault condition location;
overlaying, on the display, an augmented reality cue on the video data of the location on the aircraft, the augmented reality cue indicating the fault condition location.

5. The method of claim 4, determining the fault condition location comprises:
determining, by an image recognition engine, a fault condition based on a comparison score generated by comparing an image of a candidate component at the location of the aircraft with a historical image of the candidate component;
determining that the candidate component comprises a fault condition based at least in part on the comparison score exceeding a threshold comparison score; and
providing the fault condition location based on a location of the candidate component.

6. The method of claim 5, further comprising:
receiving a selection of the augmented reality cue; and
toggling, on the display, between the historical image of the candidate component and the image of the candidate component.

7. The method of claim 4, wherein the augmented reality cue comprises an arrow pointing towards the fault condition location.

8. The method of claim 1, wherein the error message comprises a fire event; and
wherein the fire event is determined by an optical fire detector.

9. A system for aircraft event visualization, the system comprising:
a processor communicatively coupled to a memory, the processor configured to:
receive fault data associated with an aircraft, the fault data comprising an error message for the aircraft;
determine a location on the aircraft associated with the error message based on one or more lookup tables associated with the aircraft; and
provide an indication of the location to a user.

10. The system of claim 9, wherein the processor is further configured to:
determine a fault associated with the aircraft based on the error message;
determine a candidate maintenance operation based on the fault;
provide the candidate maintenance operation to the user.

11. The system of claim 9, wherein providing the indication of the location to the user comprises:
generating a graphical representation of the aircraft;
displaying the graphical representation of the aircraft on a display;
overlaying the indication on the location on the aircraft in the graphical representation.

12. The system of claim 11, wherein the processor is further configured to:
receive video data associated with the location on the aircraft;
segment the video data into one or more images;
determine historical images for installed components at the location on the aircraft based on the one or more images;
compare the one or more images with the historical images to determine a fault condition location;
overlay, on the display, an augmented reality cue on the video data of the location on the aircraft, the augmented reality cue indicating the fault condition location.

13. The system of claim 12, determining the fault condition location comprises:
determining, by an image recognition engine, a fault condition based on a comparison score generated by comparing an image of a candidate component at the location of the aircraft with a historical image of the candidate component;
determining that the candidate component comprises a fault condition based at least in part on the comparison score exceeding a threshold comparison score; and
providing the fault condition location based on a location of the candidate component.

14. The system of claim 13, wherein the processor is further configured to:
receive a selection of the augmented reality cue; and
toggle, on the display, between the historical image of the candidate component and the image of the candidate component.

15. A computer program product for aircraft event visualization, the computer program product comprising a non-transitory computer readable medium with instruction embedded therein, the instructions operable to cause a processor to perform:
receiving fault data associated with an aircraft, the fault data comprising an error message for the aircraft;
determining a location on the aircraft associated with the error message based on one or more lookup tables associated with the aircraft; and
providing an indication of the location to a user.

16. The computer program product of claim 15, further comprising:
determining a fault associated with the aircraft based on the error message;
determining a candidate maintenance operation based on the fault;
providing the candidate maintenance operation to the user.

17. The computer program product of claim 15, wherein providing the indication of the location to the user comprises:
generating a graphical representation of the aircraft;
displaying the graphical representation of the aircraft on a display;
overlaying the indication on the location on the aircraft in the graphical representation.

18. The computer program product of claim 17, further comprising:
receiving video data associated with the location on the aircraft;
segmenting the video data into one or more images;
determining historical images for installed components at the location on the aircraft based on the one or more images;
comparing the one or more images with the historical images to determine a fault condition location;
overlaying, on the display, an augmented reality cue on the video data of the location on the aircraft, the augmented reality cue indicating the fault condition location.

19. The computer program product of claim 18, determining the fault condition location comprises:
determining, by an image recognition engine, a fault condition based on a comparison score generated by comparing an image of a candidate component at the location of the aircraft with a historical image of the candidate component;
determining that the candidate component comprises a fault condition based at least in part on the comparison score exceeding a threshold comparison score; and
providing the fault condition location based on a location of the candidate component.

20. The computer program product of claim 19, further comprising:
receiving a selection of the augmented reality cue; and
toggling, on the display, between the historical image of the candidate component and the image of the candidate component.
